(19) United States
(12) Patent Application Publication
(10) Pub. No.: US 2008/0030255 A1
(43) Pub. Date: Feb. 7, 2008

(54) SWITCH CIRCUIT AND SWITCH DEVICE

(75) Inventor: Tomonori Okashita, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: NEC ELECTRONICS CORPORATION, Kanagawa (JP)

(21) Appl. No.: 11/831,302

(22) Filed: Jul. 31, 2007

(30) Foreign Application Priority Data
Aug. 2, 2006 (JP) 2006-211341

(51) Int. Cl. H03K 17/20

(52) U.S. Cl. 327/407; 327/365; 327/415

(57) ABSTRACT

A switch circuit comprising a plural of switch elements and a control circuit operative to simultaneously shut off all of the switch elements. When forming a switch device by the combination of plural switch circuits, no other additional switches connected in series in the subsequent stage is required for shutting off unintentional signals from other input terminals.

### BACKGROUND OF THE INVENTION

1. Field of the Invention

The present invention is related to a switch circuit and a switch device, for use in a communication device or cellular phone terminal, and more specifically to a switch circuit and a switch device having plural switch elements.

2. Description of Related Art

A switch circuit of one input many output type or many input one output type, made on a compound semiconductor integrated circuit of such as GaAs (Gallium Arsenide), has been used which accommodate with the radio frequency circuit in a communication device or a cellular phone terminal. In case of radio frequency circuit, impedance matching is required for a switch circuit in order to equalize the output impedance of output node with the input impedance of the receiving circuit connected to the output node.

As disclosed in the patent documents JP-A-H6-140893, JP-A-H8-223021, JP-A-2000-357917, one input many output or many input one output type switch circuits attempt to decrease the insert loss of the switch element by using a distribution arrangement, in which plural switches are connected in parallel so as to decrease the number of switch elements through which signal passes. FIG. 1 and FIG. 2 show schematic diagrams illustrating the conventional switch circuit.

FIG. 1 shows a schematic diagram of four (4) input one (1) output type switch circuit. The four input one output type switch circuit shown in FIG. 1 has four switches S1 to S4. These switches S1 to S4 are connected in parallel, and one node is commonly connected to the output terminal OUT. A decoder controls the on- and off-state of these switches S1 to S4. In this example, one of these four switch elements connecting the output terminal OUT and input terminals IN-1 to IN-4 is always turned ON.

As shown in FIG. 2, when configuring an eight (8) input one (1) output type switch device by combining two integrated circuits each comprising a four input one output type switch circuit, a two (2) input one (1) output type switch circuit is required to be connected as their subsequent stage in order to select one of these four input one output type switch circuits to output signals.

As have been described above, in the conventional switch circuit, there is a problem that when plural switch circuits is combined, another additional switch circuit connected in series in the subsequent stage is needed, and that the gain of the switch device decreases because of the insert loss caused by the additional switch circuit.

In FIG. 3 there is shown a schematic diagram of a two (2) input two (2) output type switch circuit, and in FIG. 4 there is shown a four input two output type switch device in which two units of two input two output type switch circuits as shown in FIG. 3 are combined. Also in this example one subsequent stage made by a two input one output type switch circuit is required to be connected in series in order to select either one of two input two output type switch circuits to output signals, there is a problem that the insert loss caused by the additional switch circuit appears as the circuit scale increases.

### SUMMARY

The switch circuit according to the present invention has plural switch elements and a control circuit operative to simultaneously shut off all of the switch elements.

The switch device according to the present invention is a switch device including a plurality of switch circuits which comprises a plurality of switch elements and a control circuit operative to simultaneously shut off all of the switch elements.

According to the switch circuit of the present invention, when combining plural switch circuits, there is no need to connect another additional switch circuit in the subsequent stage, so that the circuit scale is minimized while the loss is decreased.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 shows a schematic diagram illustrating a conventional four input one output type switch circuit;

FIG. 2 shows a schematic diagram illustrating a conventional eight input one output type switch device;

FIG. 3 shows a schematic diagram illustrating a conventional two input two output type switch circuit;

FIG. 4 shows a schematic diagram illustrating a conventional four input two output type switch device;

FIG. 5 shows a schematic diagram illustrating a switch circuit according to first embodiment;

FIG. 6 shows a schematic diagram illustrating a four input one output type switch circuit according to the first embodiment;

FIG. 7 shows a schematic diagram illustrating a specific example for shutting off all switches according to the first embodiment;

FIG. 8 shows a schematic diagram illustrating an eight input one output type switch device according to the first embodiment;

FIG. 9 shows a schematic diagram illustrating a one input four output type switch circuit according to the first embodiment;

FIG. 10 shows a schematic diagram illustrating a one input eight output type switch device according to the first embodiment;

FIG. 11 shows a schematic diagram illustrating an n-input m-output type switch circuit according to second preferred embodiment;

FIG. 12 shows a schematic diagram illustrating a two input two output type switch circuit according to the second embodiment;

FIG. 13 shows a schematic diagram illustrating a four input two output type switch device according to the second embodiment;

FIG. 14 shows a circuit diagram illustrating an exemplary transfer gate embodying an SPST switch, a switch element; and

FIG. 15 shows a circuit diagram illustrating an exemplary transfer gate including f our field effect transistors connected in series, embodying an SPST switch, a switch element.

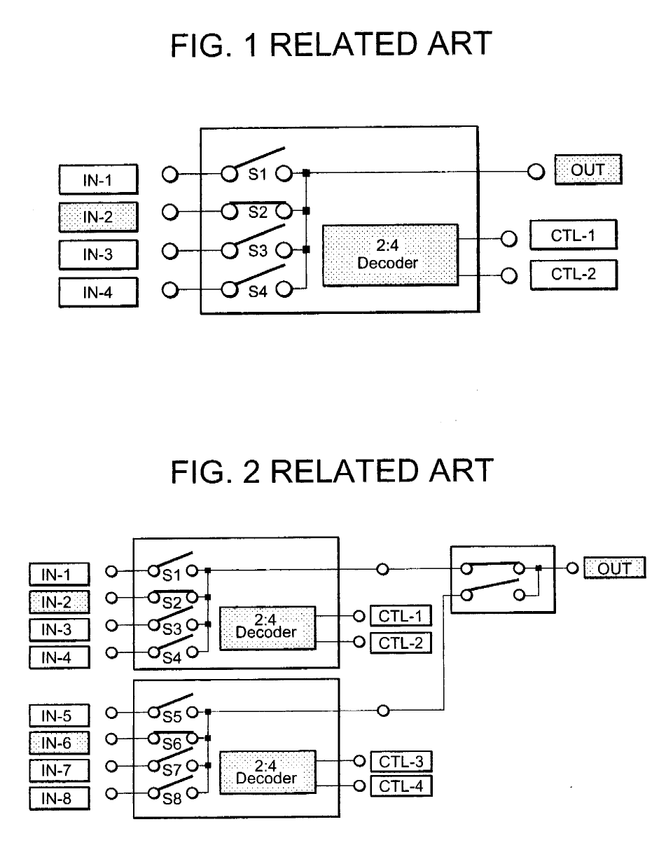

### DETAILED DESCRIPTION OF THE PREFERRED EMBODIMENTS

The invention will be now described herein with reference to illustrative embodiments. Those skilled in the art will recognize that many alternative embodiments can be accomplished using the teaching of the present invention and that the invention is not limited to the embodiments illustrated for explanatory purposes.

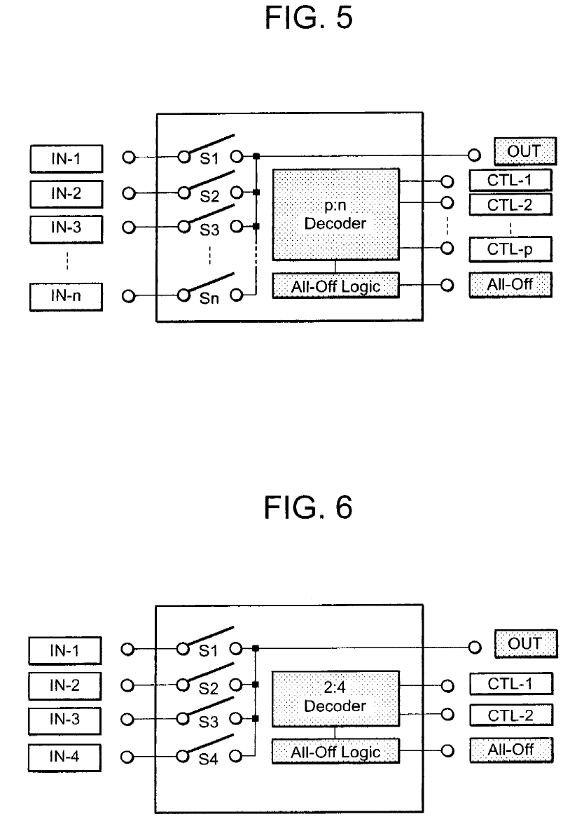

Now some embodiments will be described in greater details herein below with reference to the accompanying drawings. FIG. 5 shows a schematic diagram of a switch circuit according to the first preferred embodiment of the present invention. As shown in FIG. 5, the switch circuit of the preferred embodiment has a switch element (referred to as SPST (single pole single throw) switches S1 to Sn), input terminals IN-1 to IN-n, output terminal OUT, a control circuit including a decoder (p:n Decorder) and a logic unit (All-Off Logic), a control signal input terminals CTL-1 to CTL-p, all switch shut off terminal ALL-Off.

The SPST switches S1 to Sn have first nodes and second nodes. First nodes of S1 to Sn are connected to input terminal (IN-1 to IN-n) and second nodes of S1 to Sn are connected to output terminal (OUT) commonly. The SPST switches form a many input (IN-1 to IN-n) one output (OUT) type switch. It should be noted here that the SPST switch is a switch for turning a signal transfer line on or off, which is used in a radio frequency (GHz range) used in a radio frequency device such as a cellular phone terminal. The SPST switch has many types such as a transfer gate type, a shunt type, a FET multiple stage type, a reflex type, a terminal node type and soon, and the SPST switch according to the present invention may be formed by either one of these types. It is preferable to form as simple as possible the signal path from the input to the output in the SPST switch, in order to suppress the insert loss of the switch, and more preferable to use an SPST switch having an FET used as a transfer gate.

The control signal input terminals CTL-1 to CTL-p are terminals for inputting switch control signals for controlling the on- and off-state of the switches S1 to Sn. The p:n Decorder outputs signals for controlling the on- and off-state of the switches S1 to Sn based on the switch control signals input to the control signal input terminals CTL-1 to CTL-p, where p is integer number and n is p-th power of 2. The switch circuit according to the preferred embodiment is to select one switch among switches S1 to Sn based on the switch control signal of p bits input to the control signal input terminals CTL-1 to CTL-p. All switch shut off terminal is a terminal for inputting the all switch shut off signal for shutting off simultaneously all switches S1 to Sn. The logic unit All-Off Logic for shutting off all switches outputs the control signal for simultaneously shutting off all the switches S1 to Sn.

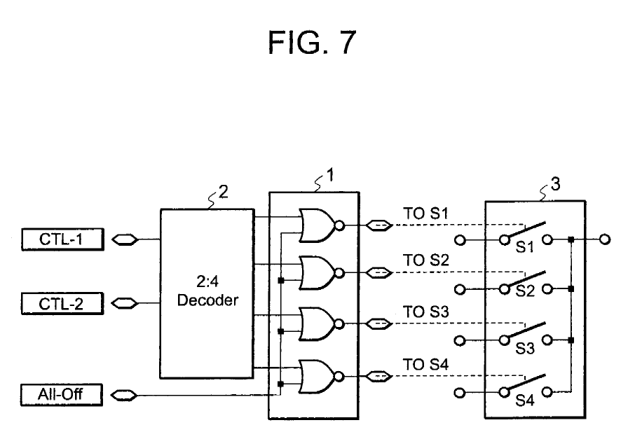

FIG. 6 shows a schematic diagram illustrating an exemplary four input one output type switch circuit, which is an example of FIG. 5. The four input one output type switch circuit shown in FIG. 6 has switches S1 to S4, input terminals IN-1 to IN-4, output terminal OUT, control signal input terminals CTL-1 and CTL-2, a 2:4 decoder, an all switch shut off terminal All-Off, and a logic unit All-Off Logic for shutting off all switches. Now the operation of the four input one output type switch circuit will be described in greater details herein below when in normal state the all switch shut off signal is not input, and when the all switch shut off signal is input, with reference to FIG. 7.

FIG. 7 shows a schematic diagram of a specific example for achieving the functionality of shutting off all switches in the four input one output type switch circuit shown in FIG. 6. The circuit shown in FIG. 7 has a switch unit 3, a control circuit (logic unit 1 and a decoder 2), control signal input terminals CTL-1 and CTL-2, and an all switch shut off terminal All-Off. The switch unit 3 has switches S1 to S4, having first nodes and second nodes, and second nodes of the switch S1 to S4 are connected commonly to form a four input one output type switch. The logic unit 1 has NOR circuits NOR1 to NOR4. These NOR circuits NOR1 to NOR4 output “H” or “L” level signal based on the input signal.

When the all switch shut off signal is not input, either one of switches S1 to S4 is turned on, through which the signal input to the input terminal is output to the output terminal OUT. Now for the purpose of explanation, it is assumed that only the switch S2 is turned on.

2-bit switch control signal for example “10”, is input to the control signal input terminals CTL-1 and CTL-2. In this case the decoder 2 will generate a signal for turning on either one of switches S1 to S4 based on the 2-bit digital signal input, and output for example “H” “L” “H” “H” to NOR1 to NOR4, respectively. The NOR circuits NOR1 to NOR4 in the logic unit 1 output NOR. In this example since the all switch shut off signal is not input to the all switch shut off terminal, the NOR circuits NOR1 to NOR4 will output signal for example “L” “H” “L” “L”. The switches S1 to S4 in the switch unit 3 turn only S2 on based on the output signal “L” “H” “L” “L” from their respective NOR circuits NOR1 to NOR4.

As can be appreciated from the foregoing description, when all switch shut off signal is not input then either one of plural switches in the switch unit is turned on to input/output signals, based on the switch control signal input to the switch control terminal. Now the operation will be described in greater details herein below when the all switch shut off signal is input to the all switch shut off terminal.

In this case also 2-bit switch control signal for example “10” is input to the control signal input terminal CTL-1 and CTL-2. The decoder 2 will generate signal for turning on either one of switches S1 to S4 based on the 2-bit digital signal input to output for example “H” “L” “H” “H” to NOR1 to NOR4, respectively. Each of the NOR circuits NOR1 to NOR4 will have the all switch shut off signal for example “H” input from the all switch shut off terminal. In this situation the NOR circuit NOR1 to NOR4 will output “L” “L” “L” “L”, respectively. The switch S1 to S4 in the switch unit 3 will turn all switches off based on the signal “L” “L” “L” “L”, output from their respective NOR circuit NORM to NOR4.

When the all switch shut off signal is input to the all switch shut off terminal, then the NOR circuits NOR1 to NOR4 output the signal for turning off their respective switches S1 to S4 irrespective of the switch control signal (“L” or “H” level) input from the switch control terminals CTL-1 and CTL-2. All switches S1 to S4 will be shut off.

Although the operation in the four input one output type switch operative to shut off all of the switch has been described, the switch circuit according to the preferred embodiment may be formed of n switches connected in parallel, having the output terminal OUT connected to either input terminals IN-1 to IN-n. In other words the many input one output (n-input 1-output) type switch circuit operative to shut off all of the switch may be arranged.

FIG. 9 shows a one input four output type switch circuit. The one input four output type switch shown in FIG. 9 has switches S1 to S4, output terminals OUT1 to OUT4, an input node TN, control signal input terminals CTL-1 and CTL-2, a 2:4 decoder, an all switch shut off terminal All-Off, and an all switch shut off logic unit All-Off Logic. The arrangement and operation of the one input four output type switch circuit shown in FIG. 9 is just similar to that of the four input one output type switch circuit shown in FIG. 6 and the detailed description thereof will be omitted.

The all switch shut off capability may be provided in the one input four output type switch circuit as similar to the four input one output type switch circuit. The switch circuit may be formed of n switches connected in parallel, having the input terminal IN necessarily connected to either one of output terminals OUT1 to OUTN. Namely a switch circuit of one input many output (1-input n-output) type having the all switch shut off capability may be arranged.

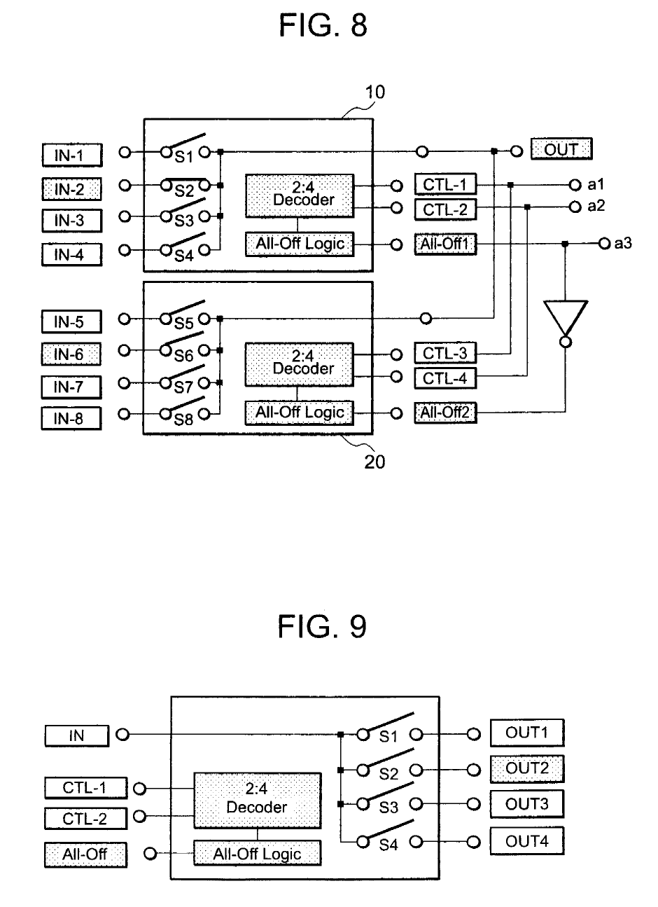

Now the arrangement of eight input one output type switch circuit by combining two sets of four input one output type switches according to the preferred embodiment (switch device herein below) will be described in greater details. FIG. 8 shows the eight input one output type switch device. In FIG. 8 the switch device has first switch circuit (referred to as switch circuit 10 herein below), and second switch circuit (referred to as switch circuit 20 herein below). The switch circuit 10 has switches S1 to S4, input terminals IN-1 to IN-4, switch control terminals CTL-1 and CTL-2, a 2:4 decoder, an all switch shut off logic circuit All-Off Logic, and an all switch shut off terminal All-Off1. The switch circuit 20 has switches S5 to S8, input terminals IN-5 to IN-8, switch control terminals CTL-3 and CTL-4, a decoder 2, a logic unit 1, and an all switch shut off terminal All-Off2. The switch control terminal CTL-1 is connected to CTL-3, and the switch control terminal CTL-2 is connected to CTL-4. The all switch shut off terminal All-Off1 and All-Off2 are interconnected through an inverter. The internal connection in the switch circuit 10 and the switch circuit 20, and the detailed operation are identical to FIG. 5 or FIG. 6 and the description thereof will be omitted.

Now the operation will be described when, assumingly, signal input to the input node IN-2 is output to the output node OUT. First, in switch circuit 10, a switch control signal is input for turning on only the switch S2, from the common terminal a1 and a2 to the switch control terminals CTL-1 and CTL-2. IN this case in the switch circuit 20 as the switch control terminals CTL-3 and CTL-4 will have the same signal as that input to the switch control terminals CTL-1 and CTL-2, the signal for turning on only the switch S6 corresponding to the switch S2 is input. At this point the signal for turning off the all switch shut off terminal All-Off1 is input from the common terminal a3 to the all switch shut off terminal All-Off1, while the signal inverted by the inverter is input to the switch shut off terminal All-Off2. By doing this only the switch S2 may be turned on.

As can be appreciated from the foregoing description, when forming an eight input one output type switch device by using four input one output type switch circuits having the all switch shut off capability, all input of the switch circuit having only the input terminal desired to be shut off (switch circuit 20) may be shut off. Therefore, when forming an eight input one output type switch circuit by combining the conventional four input one output type switch circuit another additional switch circuit must have been connected in series thereto in order to shut off the unintentional signals from the input terminals (S5 to S8), however in the switch circuit having the all switch shut off capability according to the preferred embodiment the another additional switch circuit connected in series in the subsequent stage is not necessary, resulting in no insertion loss caused by the additional circuit. In addition, by connecting the switch control terminals CTL-1 an CTL-3, and the switch control terminals CTL-2 and CTL-4 with the common terminals a1 and a2, on-off control of the switches S1 to S8 may be achieved with less number of terminals. When forming an eight input one output a type switch circuit by using four input one output type switch circuits, by providing an inverter between the all switch shut off terminal All-Off1 and All-Off2, signal may be input to both all switch shut off terminals from only one single terminal.

When forming an eight input one output switch device by combining two sets of four input one output switch circuits, the eight input one output switch circuit may be operated as one switch circuit by providing common terminals a1, a2, or a3 each connected to the switch control terminals CTL-1 and CTL-3, switch control terminals CTL-2 and CTL-4, and all switch shut off terminals Ali-Off1 and All-Off2.

As described above an eight input one output switch device is achieved by using four input one output switch integrated circuits without an insert loss of additional switch circuit and designing newly an eight input one output switch circuit.

In the present preferred embodiment an eight input one output type switch device is formed by using four input one output type switches, however many input one output (n-input 1-output) type switch having the all switch shut off capability may be used to form an (m×n) input one output type switch circuit. Also in such a case no additional switch circuit connected in series in the subsequent stage is needed because each n-input 1-output type switch circuit has the capability of all switch shut off.

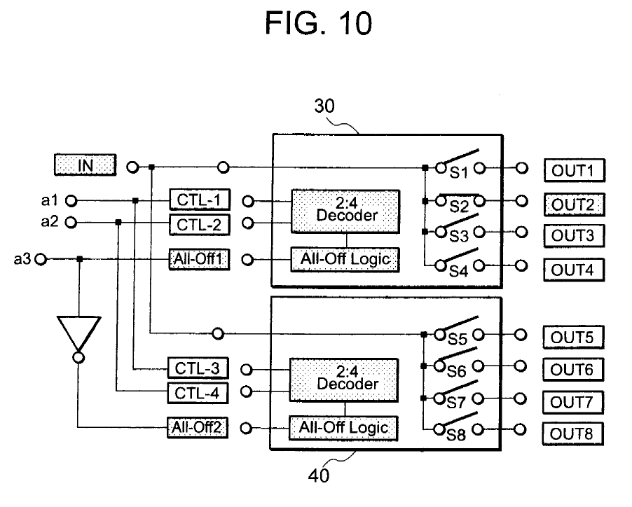

In addition, when forming a one input eight output type switch device by using one input four output type switch circuit having the all switch shut off capability as shown in FIG. 10, all input to the switch circuit (switch circuit 40) having only the input terminal desired to be shut off. Therefore the additional switch circuit connected in series in the subsequent stage is not required for shutting off the signal from unintentional input terminals (IN-5 to IN-8), which circuit was necessary when forming an eight input one output type switch circuit by combining the conventional four input one output type switch circuits.

Moreover, although in the above embodiment a one input eight output type switch has been disclosed using one input four output type switches, one input (m×n) output type switch device may be formed by using one input many output (1-input n-output) type switch circuits each having the all switch shut off capability. In that case also an additional switch circuit connected in series in the subsequent stage is not necessary.

As can be appreciated from the foregoing description, in the switch circuit having the all switch shut off capability according to the preferred embodiment, for example when forming (n×m) input one output type switch device by combining m switch circuits of n-input 1-output type, an additional switch connected in series in the subsequent stage is not necessary because all input to the switch circuits having the input terminals desired to be shut off. This allows therefore the insertion loss to be decreased caused by the series connection of switch circuits.

### Second Embodiment

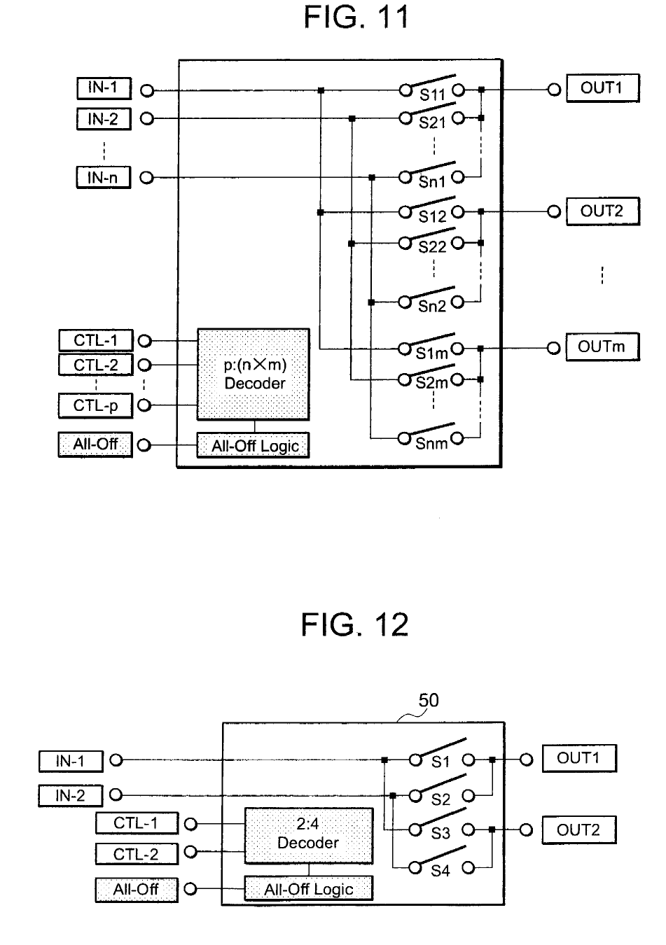

In the present embodiment a switch circuit having plural input terminals and plural output terminals, namely n-input m-output type switch circuit will be described in greater details. The arrangement and the operation of the switch circuit identical to the first preferred embodiment will be omitted. FIG. 11 shows a schematic diagram of a switch circuit of n-input m-output type according to the preferred embodiment. The n-input m-output type switch circuit shown in FIG. 11 has switches S11 to Sn1, S12 to Sn2, and S1m to Snm, input nodes In-1 to IN-n, output nodes OUT1 to OUTm, control signal input terminals CTL-1 to CTL-p, a p: (n×m) decoder, an all switch shut off logic circuit All-Off Logic, and all switch shut off terminal All-Off. The logic circuit All-Off Logic for shutting off all switches outputs control signal for turning off simultaneously all switches S11 to Sn1, S12 to Sn2, S1m to Snm, based on the all switch shut off signal input from the all switch shut off terminal All-Off. When an all switch shut off signal is input from the all switch shut off terminal, all switches S11 to Sn1, S12 to Sn2, and S1m to Snm will be shut off regardless of the switch control signal input from the switch control terminals CTL-1 to CTL-p (“L” or “H” level). In FIG. 12, a switch circuit of two input two output type, having the all switch shut off terminal will be described in greater details.

FIG. 12 shows a switch circuit having switches S9 to S12, input terminals IN-1 and IN-2, output terminals OUT1, and OUT2, a 2:4 decoder, a logic circuit All-Off Logic for shutting off all switches, control signal input terminals CTL-1 and CTL-2, and an all switch shut off terminal All-Off. The input terminal IN-1 is connected to switch elements S1 and S3, while the input terminal IN-2 is connected to switch elements S2 and S3. The output node OUT1 is connected to the common terminal of the switch elements S1 and S2, the output node OUT2 is connected to the common terminal of the switch elements S3 and S4. When, for example, no all switch shut off signal is input from the all switch shut off terminal, then the signal input from the input terminal IN-1 is output to the output terminal OUT1 or OUT2, and the input signal from the input terminal IN-2 is output to the output terminal OUT1 or OUT2. In this situation, when an all switch shut off signal is applied, then the logic unit 1 will output the signal for turning off each respective switches S1 to S4 regardless of the switch control signal input from the switch control terminals CTL-1 and CTL-2 (“L” or “H” level). Thus all switches S1 to S4 will be shut off.

The operation of a two input two output type switch circuit having the all switch shut off capability has been described. The switch circuit according to the preferred embodiment is formed of n switches connected in parallel, capable of disconnecting both output terminals OUT1 and OUT2 from the input. By forming a switch circuit having the capability as have been described above, an n-input m-output type switch circuit having all switch shut off capability may be constructed.

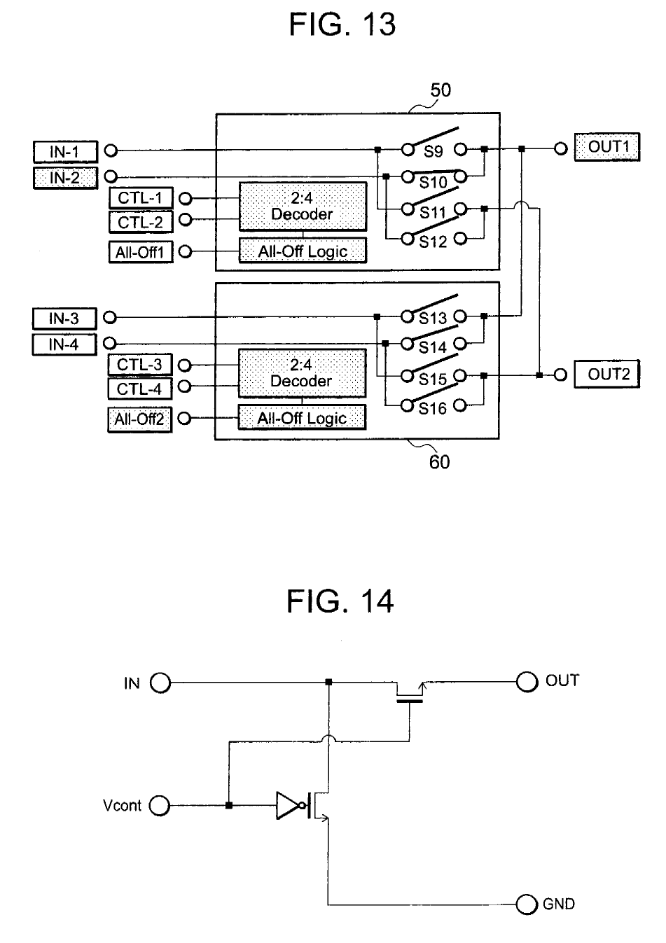

Now a four input two output type switch circuit (referred to as switch device herein below) by forming from the combination of two sets of two input two output type switches according to the preferred embodiment will be described in greater details. FIG. 13 shows a schematic diagram of a four input two output type switch device. The switch device shown in FIG. 13 includes a fifth switch circuit (referred to as switch circuit 50), and a sixth switch circuit (referred to as switch circuit 60). The switch circuit 50 has switches S9 to S12, input terminals IN-1, and IN-2, an output terminal OUT1, switch control terminals CTL1, and CTL-2, a 2:4 decoder, a logic circuit All-Off Logic for shutting off all switch, and an all switch shut off terminal All-Off1. The switch circuit 60 has switches S13 to S16, input terminals IN-3, and IN-4, switch control terminals CTL-3, and CTL-4, a 2:4 decoder, a logic circuit All-Off Logic for shutting off all switches, and an all switch shut off terminal All-Off2. In this example the common nodes of the switches S9 and S10 and of the switches S13 and S14 are connected to the output terminal OUT1, the common nodes of the switches S11 and S12 and of the switches S15 and S16 are connected to the output terminal OUT2. The internal connection and the operation of the switch circuit 50 and the switch circuit 60 are identical to those shown in FIG. 11 and in FIG. 12 the detailed description thereof will be omitted.

Now the operation will be described in greater details when the signal input to the input terminal IN-2 is output to the output terminal OUT1. In the switch circuit 50 a switch control signal for turning on only the switch S10 is fed to the switch control terminal CTL-1 and CTL-2. In this case the all switch shut off signal is not input to the all switch shut off terminal All-Off1, however the all switch shut off signal is provided to the switch shut off terminal All-Off2 in the switch circuit 60. In other words the switch S10 is turned on in the switch circuit 50. On the other hand all switches S13 to S16 are turned off in the switch circuit 60. Therefore the switch device is capable of turning only the switch S10 on. Since the switch S10 only is turned on, the signal input to the input terminal IN-2 is passed through to the output terminal OUT1.

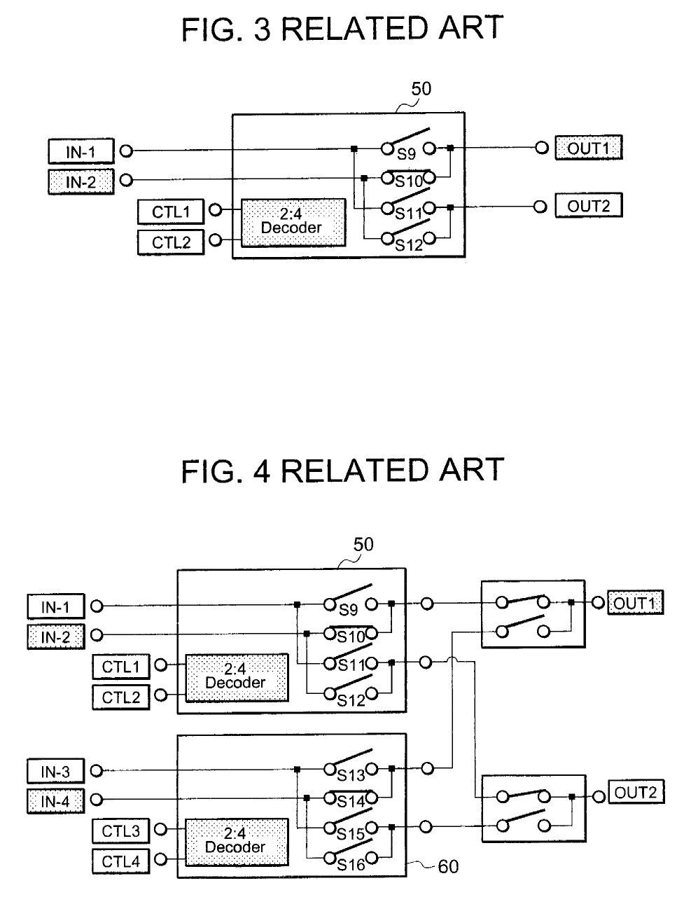

As can be appreciated from the foregoing description, All input of the switch circuit (the switch circuit 60) having only the input terminals desired to be shut off may be shut off when forming a four input two output type switch device by using two input two output type switch circuits having the all switch shut off capability. Accordingly, although another additional switch circuit is needed to be connected in series in the subsequent stage for shutting off the unintentional signals from the input terminals (S13 to S16) when forming a four input two output type switch device by combining the conventional two input two output type switch circuits (see FIG. 3 and FIG. 4), the switch circuit having the all switch shut off capability according to the preferred embodiment does not require the additional switch circuit connected in series in the subsequent stage.

Also, although in the present preferred embodiment a four input two output type switch device has been formed by using two input two output type switch circuits, a many input many output type switch device may be formed by using many input many output (n-input m-output) type switch circuits having the all switch shut off capability. Because each n-input m-output type switch circuit has the all switch shut off capability provided in this case, no other additional switch circuit is required connected in series in the subsequent stage.

In this manner, in the switch circuit having the all switch shut off capability according to the preferred embodiment, since all input of the switch circuits having the input terminals desired to be shut off may be disconnected when forming a many input many output type switch device by combining n-input m-output type switch circuits, no additional switch is required connected in series in the following stage. Accordingly the insertion loss caused by the serial connection of switch circuits is allowed to decrease.

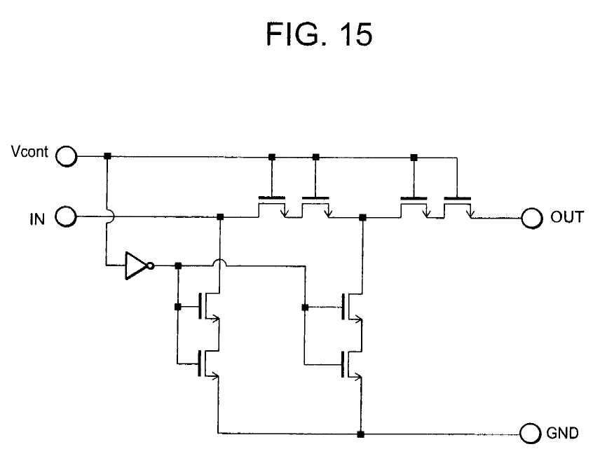

In both first and second preferred embodiments, the unitary switch element, SPST switch, may be achieved by any one of a number of circuits as have been described above. As a specific example a transfer gate type circuit is shown in FIG. 14 and in FIG. 15.

FIG. 14 shows a switch circuit using a field effect transistor Tr1 connected between the input and the output as the transfer gate, and a shunt transistor Tr2 between the input terminals. The control signal Vcont is input to the gate terminal of the transfer gate, the inverted signal of the control signal Vcont is input to the gate terminal of the shunt transistor. For conducting between the input and the output the Vcont is turned to high level to make Tr1 on and Tr2 off. For disconnecting between the input and the output the Vcont is turned to low level to make Tr1 off and Tr2 on. When disconnected, as the circuit is appeared to have high impedance when viewing from the output terminal, only the impedance of the SPST switch which is turned on is viewed from the output terminal to which plural SPST switches are connected. Thus other SPST switches turned off does not affect the input-output characteristics of the circuit.

FIG. 15 shows a switch circuit achieving the transfer gate by the serial connection of four field effect transistors, which circuit has much superior insulation characteristics when turned off in comparison with the circuit shown in FIG. 14.

Although the preferred embodiments according to the present invention has been described in greater details, those skilled in the art may recognize that many changes and modifications may be made in the invention without departing from the spirit and scope thereof.

It is apparent that the present invention is not limited to the above embodiments, but may be modified and changed without departing from the scope and spirit of the invention.

What is claimed is:

1. A switch circuit comprising a plurality of switch elements and a control circuit operative to simultaneously shut off all of the switch elements.

2. The switch circuit according to claim 1, wherein
the switch element is connected between a first node and a second node, and
the control circuit turns on one of the switch elements or shut off all of the switch elements.

3. The switch circuit according to claim 2, wherein the control circuit comprises
a decoder for turning on one of the switch elements based on a switch control signal, and
a logic unit for turning off all of the switch elements based on a switch shut off signal.

4. The switch circuit according to claim 3, wherein
the decoder receives p signals of the switch control signal and outputs p-th power of 2 signals (p:integer), and the logic unit receives the p-th power of 2 signals outputted from the decoder and the switch shut off signal and outputs p-th power of 2 signals for turning on one of the switch elements or for turning off all of the switch elements.

5. The switch circuit according to claim 4, wherein
the logic unit comprises a plurality of logic elements which receives one signal of the p-th power of 2 signals outputted from the decoder and the switch shut off signal and outputs one signal for turning on or off one of the switch elements.

6. The switch circuit according to claim 2, wherein
all of the first nodes of the switch elements are common connected.

7. The switch circuit according to claim 6, wherein
the switch circuit comprises an input terminal and a plurality of output terminals, and
the first nodes common connected are connected to the input terminal and each of the second nodes is connected to one of the output terminals.

8. The switch circuit according to claim 6, wherein
the switch circuit comprises a plurality of input terminals and an output terminals, and
the first nodes common connected are connected to the output terminal and each of the second nodes is connected to one of the input terminals.

9. The switch circuit according to claim 2, wherein
the first nodes of the switch elements are separated to a plurality of groups and the first nodes of each group are common connected,
the second nodes of the switch elements are separated a plurality of groups and the second nodes of each group are common connected.

10. The switch circuit according to claim 9, wherein
the switch circuit comprises a plurality of input terminals and a plurality of output terminals, and
the first nodes common connected of each group are connected to one of the input terminals and the second nodes common connected of each group are connected to one of the output terminals.

11. The switch circuit according to claim 10, wherein
each of the input terminals and each of the output terminals are connected through one of the switch elements.

12. A switch device including a plurality of switch circuits which comprises a plurality of switch elements and a control circuit operative to simultaneously shut off all of the switch elements.

13. The switch device according to claim 12, wherein
the switch device selectively uses one of the switch circuits.

14. The switch device according to claim 13, wherein
the switch circuit is formed as a integrated circuit, and
the switch device is formed as a module comprising a plurality of integrated circuits.

15. The switch device according to claim 13, wherein
the switch circuit comprises an input terminal and an output terminal,
the switch device comprises an input terminal and an output terminal, and
the input terminal of the switch circuit is connected directly to the input terminal of the switch device,
the output terminal of the switch circuit is connected directly to the output terminal of the switch device.

16. The switch device according to claim 15, wherein
the control circuit of the switch circuit comprises a logic unit for turning off all of the switch elements based on a switch shut off signal, and
only one of the switch shut off signals of the switch circuits is inputted selectively for using one of the switch circuits.
